(19) United States
(12) Patent Application Publication
(10) Pub. No.: US 2026/0047242 A1
(43) Pub. Date: Feb. 12, 2026

(54) SEMICONDUCTOR ELEMENT

(71) Applicant: EPISTAR CORPORATION, Hsinchu (TW)

(72) Inventors: Ching-Han LIAO, Hsinchu (TW); Jih-Kang CHEN, Hsinchu (TW); Tzong-Liang TSAI, Hsinchu (TW); Chen OU, Hsinchu (TW); Chi-Ling LEE, Hsinchu (TW); Ching-Hua SU, Hsinchu (TW)

(21) Appl. No.: 19/290,128

(22) Filed: Aug. 4, 2025

Related U.S. Application Data
(60) Provisional application No. 63/681,383, filed on Aug. 9, 2024.

(30) Foreign Application Priority Data
Jul. 14, 2025 (TW) 114126569

(51) Int. Cl. H10H 20/831; H04B 10/50; H10H 20/819

(52) U.S. Cl. CPC H10H 20/8314; H04B 10/502; H10H 20/819

(57) ABSTRACT

A semiconductor element is provided. The semiconductor element includes: a semiconductor stack including a mesa portion and a recessed portion; a contact layer formed on the mesa portion; an insulating layer formed on the semiconductor stack and the contact layer, wherein the insulating layer includes a first opening formed on the mesa portion; and an electrode layer formed on the insulating layer, wherein the electrode layer is electrically connected to the contact layer. In a plan view, the mesa portion includes a first centroid, the contact layer includes a second centroid, and the first opening includes a third centroid, and a distance between the first centroid and the third centroid is greater than a distance between the second centroid and the third centroid.

### REFERENCE TO RELATED APPLICATION

This application claims the right of priority based on U.S. Provisional Application Ser. No. 63/681,383, filed on Aug. 9, 2024, TW application No. 114126569, filed on Jul. 14, 2025, and the content of which are hereby incorporated by references in their entireties.

### TECHNICAL FIELD

The application relates to a semiconductor element, and more particularly to a semiconductor light-emitting device, as well as an optical communication device comprising the semiconductor light-emitting device and the method of using the optical communication device.

### DESCRIPTION OF BACKGROUND ART

A semiconductor element includes a III-V group semiconductor compound, such as gallium phosphide (GaP), gallium arsenide (GaAs), gallium nitride (GaN), or aluminum nitride (AlN). The semiconductor element may be a semiconductor optoelectronic device, for example, the light-emitting diode (LED), the laser, the photodetector, or the solar cell. The semiconductor optoelectronic device may also be the power device or the acoustic wave device. Taking the light-emitting diode as an example, the LED features the low power consumption, the low heat generation, the long lifespan, the small size, the fast response, and the excellent optoelectronic properties, such as the stable light emission wavelength. Therefore, LEDs have been widely used in the home appliances, the vehicles, the industrial equipment, the computers, the communications, and the consumer electronic products.

The light-emitting diode includes a substrate, an n-type semiconductor layer, an active layer, and a p-type semiconductor layer formed on the substrate, and a p-type electrode and an n-type electrode respectively formed on the p-type semiconductor layer and the n-type semiconductor layer. When the light-emitting diode is driven by a forward bias through the electrodes, the holes from the p-type semiconductor layer and the electrons from the n-type semiconductor layer combine in the active layer to emit the light. However, as the light-emitting diodes are applied to various optoelectronic products and the size of the light-emitting diode is reduced, how to maintain the optoelectronic properties becomes a goal of research and development for those skilled in the art.

### SUMMARY OF THE APPLICATION

A semiconductor element includes a semiconductor stack including a mesa portion and a recessed portion; a contact layer disposed on the mesa portion; an insulating layer disposed on the semiconductor stack and the contact layer, wherein the insulating layer includes a first opening formed on the mesa portion; and an electrode layer disposed on the insulating layer, wherein the electrode layer is electrically connected to the contact layer. In a plan view, the mesa portion includes a first centroid, the contact layer includes a second centroid, and the first opening includes a third centroid, and a distance between the first centroid and the third centroid is greater than a distance between the second centroid and the third centroid.

In some embodiments, in a plan view, the contact layer includes a dimension decreased in a direction toward the recessed portion.

In some embodiments, the dimension of the contact layer is decreased in a step-by-step manner.

In some embodiments, the dimension of the contact layer is continuously decreased.

In some embodiments, the insulating layer further includes a second opening located in the recessed portion, and the electrode layer includes a first electrode layer and a second electrode layer. The first electrode layer is located on the mesa portion and is electrically connected to the contact layer. The second electrode layer is located in the recessed portion and is electrically connected to the semiconductor stack through the second opening.

In some embodiments, a projection of the contact layer on the semiconductor stack and a projection of the second electrode layer on the semiconductor stack are not overlapped with each other.

In some embodiments, the semiconductor element further includes a current spreading layer disposed on the contact layer. The current spreading layer includes a first portion having a second contact surface and contacting the contact layer and a second portion having a first contact surface and contacting the semiconductor stack, wherein the first opening exposes at least a part of the first portion of the current spreading layer, and the first electrode layer is electrically connected to the current spreading layer.

In some embodiments, a projection of the current spreading layer on the semiconductor stack is completely covered by the projection of the contact layer on the semiconductor stack.

In some embodiments, in a plan view, the current spreading layer extends beyond an edge of the contact layer in a width direction and includes a first contact surface with the semiconductor stack, and the contact layer includes a second contact surface with the semiconductor stack, wherein an area of the first contact surface is smaller than an area of the second contact surface.

In some embodiments, the semiconductor stack sequentially includes a first semiconductor layer, an active layer, and a second semiconductor layer, and the contact layer is directly disposed on the second semiconductor layer.

In some embodiments, the second semiconductor layer is substantially rectangular, includes two opposing shorter sides and two opposing longer sides, and a shortest distance between any side of the contact layer and any side of the second semiconductor layer is not less than 0.5% of the length of the shorter side of the second semiconductor layer.

In some embodiments, in the plane view, the second semiconductor layer is substantially rectangular, includes two opposing shorter sides and two opposing longer sides, and the distance between the first centroid and the second centroid is 0.5%˜49% of the length of the longer side.

In some embodiments, in a cross-sectional view, the second semiconductor layer is substantially rectangular or trapezoidal, includes two opposing shorter sides and two opposing longer sides, and the distance between the first centroid and the second centroid is 0.5% to 49% of the length of the longer side.

In some embodiments, the second semiconductor layer is substantially rectangular and includes a first side and a second side that are opposite to each other in the direction extending from the first electrode layer toward the second electrode layer. The contact layer includes a third side and a fourth side that are opposite to each other in the same direction. In that direction extending from the first electrode layer toward the second electrode layer, the first side, the third side, the fourth side, and the second side are sequentially disposed, wherein the shortest distance between the second side and the fourth side is greater than the shortest distance between the first side and the second side.

In some embodiments, in the direction extending from the first electrode layer toward the second electrode layer, a shortest distance between the contact layer and the second semiconductor layer is shorter than a shortest distance between the contact layer and the recessed portion.

In some embodiments, the shortest side of the semiconductor element has a length of 2˜20 μm.

In some embodiments, the contact layer occupies 1% to 25% of the area of the mesa portion and occupies 1% to 12% of the area of the semiconductor element.

Another embodiment of the present application provides an optical communication device including the semiconductor element as described above.

Another embodiment of the present application provides a method of using the optical communication device as described above, including the step of operating the optical communication element at a current greater than 1 mA or at a current density greater than 1000 A/cm², wherein the optical communication element includes a bandwidth greater than 1 GHz at −3 dB.

### BRIEF DESCRIPTION OF THE DRAWINGS

The embodiments of the disclosure will be described in detail below with reference to the accompanying drawings. It should be noted that various features are not drawn to scale and are for illustrative purposes only. In fact, the dimensions of the elements may be enlarged or reduced to clearly demonstrate the technical features of the embodiments of the present disclosure.

FIG. 1A illustrates a plan view of a semiconductor element 1 according to a first embodiment of the present application.

FIG. 1B illustrates a cross-sectional view taken along line A-A′ of FIG. 1A.

FIG. 2 illustrates the plan view of the semiconductor element 1 according to the first embodiment of the present application.

FIG. 3 illustrates a plan view of a semiconductor element 2 according to a second embodiment of the present application.

FIG. 4A illustrates a plan view of a semiconductor element 3A according to a third embodiment of the present application.

FIG. 4B illustrates a schematic diagram of a variation example of the contact layer of a semiconductor element 3B.

FIG. 5A illustrates a plan view of a semiconductor element 4 according to a fourth embodiment of the present application.

FIG. 5B illustrates a cross-sectional view taken along line A-A′ of FIG. 5A.

FIG. 6A illustrates a plan view of a semiconductor element 5 according to a fifth embodiment of the present application.

FIG. 6B illustrates a cross-sectional view taken along line A-A′ of FIG. 6A.

FIG. 7A illustrates a plan view of a semiconductor element 6 according to a sixth embodiment of the present application.

FIG. 7B illustrates a cross-sectional view taken along line A-A′ of FIG. 7A.

FIGS. 8A-8F illustrate an experimental comparison between the semiconductor element 1A according to the first embodiment of the present application and a semiconductor element 8 of a comparative example.

FIG. 9 illustrates a cross-sectional view of a light-emitting module 100 according to an embodiment of the present application.

FIG. 10 illustrates a schematic plan view of a display module 105 according to an embodiment of the present application.

### DETAILED DESCRIPTION OF PREFERRED EMBODIMENTS

In order to make the description of the present application more detailed and complete, please refer to the following descriptions of the embodiments together with the relevant drawings. However, the embodiments shown below are provided for illustrating the semiconductor element of the present application. In some embodiments, the semiconductor element may be a semiconductor optoelectronic device such as a light-emitting diode (LED), laser, photodetector, solar cell, or a power device. Taking a light-emitting device as an example, the structure of the light-emitting device includes a p-type semiconductor layer, an n-type semiconductor layer, and an active layer. The active layer includes a light-emitting layer capable of emitting the light of different wavelengths according to the material composition of the active layer.

The following embodiments are provided to illustrate the various examples of the semiconductor elements. However, it is understood that the semiconductor elements in these embodiments are only for illustration purposes and are not intended to limit the present application to the following embodiments. In addition, the size, the material, the shape, the relative configuration, etc. of the components illustrated in the embodiments of the present application are not limited thereto and are only for illustrations. Moreover, the size or the position relationship of the components shown in each figure may be exaggerated for the purpose of clear description. In the following description, in order to appropriately omit the detailed description, the same or the similar components are illustrated with the same name and symbol.

In the present application, unless otherwise specified, the general formula AlGaN series represents AlₐGa₍₁₋ₐ₎N, wherein 0≤a≤1; the general formula InGaN series represents In_{b}Ga_{(1-b)}N, wherein 0≤b≤1; the general formula AlInGaN series represents Al_{c}(In_{d}Ga_{(1-c-d)}N, wherein 0≤c≤1, 0≤d≤1. The general formula AlInGaP series represents (AlₑIn₍₁₋ₑ₎)_{1-f}Ga_{f}P, wherein 0≤e≤1, 0≤f≤1; the InGaAsP series represents In_{g}Ga_{(1-g)}ASₕP₍₁₋ₕ₎, wherein 0≤g≤1, 0≤h≤1. Adjusting the content of an element can achieve different purposes, such as but not limited to adjusting the energy band gap or adjusting the main emission wavelength of the light-emitting device.

The composition and dopants of each layer of the semiconductor element exemplified in the present application may be analyzed by any suitable method, such as a secondary ion mass spectrometer (SIMS).

The width or thickness of each layer or structure of the semiconductor element exemplified in the present application may be analyzed by any suitable method, such as transmission electron microscopy (TEM) or scanning electron microscopy (SEM), so as to correlate the width or the thickness with the depth position of each layer shown in, for example, the spectrum of the secondary ion mass spectrometer (SIMS).

In detail, the following embodiments will be illustrated using the light-emitting device as an example of the semiconductor element. In the present application, the dimension in the Y direction in the drawings is defined as the width, and the dimension in the X direction is defined as the length.

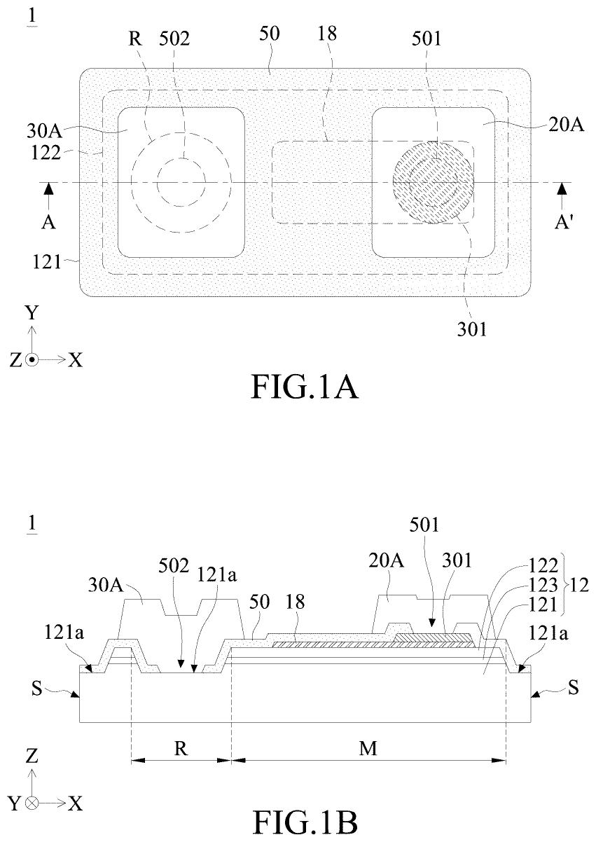

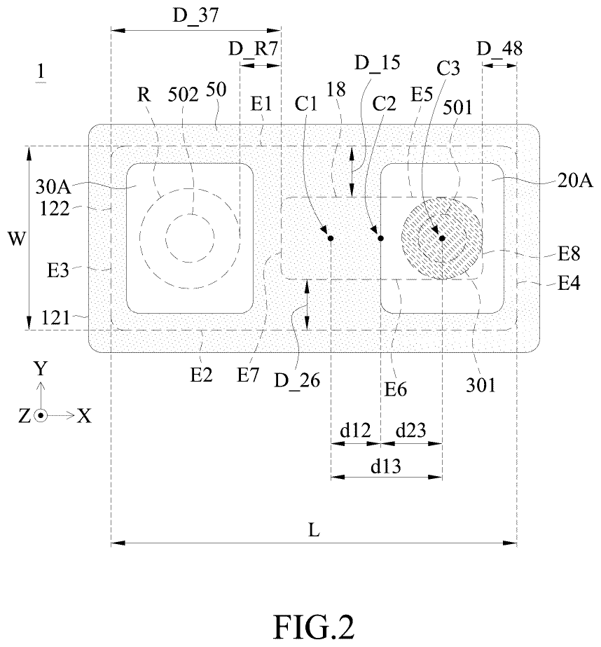

FIGS. 1A and 2 illustrate a plan view of a semiconductor element 1 according to the first embodiment of the present application. FIG. 1B illustrates a cross-sectional view taken along line A-A′ in FIG. 1A. In an embodiment, the semiconductor element 1 may be a light emitting diode (LED) and has a size (for example, diagonal, width, length, or height) of 2 to 5 μm, 5 to 10 μm, 10 to 20 μm, 20 to 50 μm, or 50 to 100 μm. In an embodiment, the shortest side of the semiconductor element 1 has a length of 2 to 20 μm, for example, 2 to 15 μm, 2 to 10 μm, or 2 to 5 μm.

As shown in FIGS. 1A and 1B, the semiconductor element 1 includes a semiconductor stack 12, a contact layer 18, a current spreading layer 301, an insulating layer 50, and an electrode layer (including a first electrode layer 20A and a second electrode layer 30A, which will be described in detail later) sequentially stacked along the Z-direction.

The semiconductor stack 12 may be formed on a substrate (not shown) by a film formation method, such as metal-organic chemical vapor deposition (MOCVD), molecular beam epitaxy (MBE), hydride vapor phase epitaxy (HVPE), or ion deposition such as sputtering or evaporation. In addition, the substrate may be separated or removed from the semiconductor stack 12 during or at the end of the manufacturing process of the semiconductor element.

Referring to FIGS. 1A and 1B, in the X direction, the semiconductor stack 12 includes a mesa portion M and a recessed portion R. In the Z direction, the semiconductor stack 12 sequentially includes a first semiconductor layer 121, an active layer 123, and a second semiconductor layer 122. The mesa portion M includes the first semiconductor layer 121, the active layer 123, and the second semiconductor layer 122, while the recessed portion R is located in the semiconductor stack 12. The first semiconductor layer 121 further includes an upper surface 121a provided as a bottom surface of the recessed portion R and not covered by the active layer 123 and/or the second semiconductor layer 122.

In an embodiment, the first semiconductor layer 121 and the second semiconductor layer 122 can be cladding layers or confinement layers. In an embodiment, the first semiconductor layer 121 and the second semiconductor layer 122 include different conductivity types, electrical properties, polarities, or doping elements for providing electrons or holes. For example, the first semiconductor layer 121 includes an n-type semiconductor, and the second semiconductor layer 122 includes a p-type semiconductor. The active layer 123 is formed between the first semiconductor layer 121 and the second semiconductor layer 122. Under a current driving, the electrons and the holes respectively injected from the first semiconductor layer 121 and the second semiconductor layer 122 combine in the active layer 123, which converts the electrical energy into the optical energy to emit the light. Optionally, the wavelength of the light emitted from the semiconductor element 1 or the semiconductor stack 12 may be adjusted by changing the material composition of one or more layers of the semiconductor stack 12.

The material of the semiconductor stack 12 includes III-V Group semiconductor compound, such as AlₓIn_{y}Ga_{(1-x-y)}N (AlInGaN series) or AlₓIn_{y}Ga_{(1-x-y)}P (AlInGaP series), wherein 0≤x, y≤1 and x+y≤1. According to the material of the active layer 123, when the material of the semiconductor stack 12 is AlInGaP series, the active layer 123 can emit the red light with a wavelength between 610 nm and 650 nm, or the yellow light with a wavelength between 550 nm and 570 nm. When the material of the semiconductor stack 12 is AlInGaN series, it can emit the blue or deep blue light with a wavelength between 400 nm and 490 nm, the green light with a wavelength between 490 nm and 550 nm, or the UV light with a wavelength between 250 nm and 400 nm. The active layer 123 includes a single heterostructure (SH), double heterostructure (DH), double-side double heterostructure (DDH), or multi-quantum well (MQW). Optionally, the material of the active layer 123 includes i-type, p-type, or n-type semiconductor.

Optionally, the semiconductor stack 12 further includes a buffer structure (not shown) located on a side opposite to the electrode layer. For example, when the semiconductor stack 12 is formed on the substrate by MOCVD, the substrate can be selected from a growth substrate suitable for epitaxy. In the formation of the semiconductor stack 12, the buffer structure can reduce the material lattice mismatch between the semiconductor stack 12 and the growth substrate and suppress the dislocations, thereby improving the epitaxy quality. The material of the buffer structure may include GaN, AlGaN, or AlN. In an embodiment, the buffer structure includes multiple sub-layers (not shown), which may include the same or different materials. In an embodiment, the buffer structure includes two sub-layers, wherein the first sub-layer and the second sub-layer can be formed by different methods. For example, the first sub-layer is formed by sputtering, and the second sub-layer is formed by MOCVD. In another embodiment, the buffer structure may further include a third sub-layer, which is formed by MOCVD, and the growth temperature of the second sub-layer is different from that of the third sub-layer. In an embodiment, the first, second, and third sub-layers may include the same material, for example, all the sub-layers include AlN.

The contact layer 18 is formed on the second semiconductor layer 122 of the mesa portion M and forms good electrical contact, such as ohmic contact, with the second semiconductor layer 122. Specifically, the material of the contact layer 18 includes a metal material or a transparent conductive material. The metal material may include, but is not limited to, gold (Au), nickel-gold (NiAu), beryllium-gold (BeAu), or germanium-gold (GeAu). The transparent conductive material may include, but is not limited to, graphene, indium tin oxide (ITO), aluminum zinc oxide (AZO), gallium-doped zinc oxide (GZO), zinc oxide (ZnO), or indium zinc oxide (IZO). In an embodiment, the contact layer 18 is transparent to the light emitted from the semiconductor stack 12, for example, having a transmittance of more than 80%. In an embodiment, the thickness of the contact layer 18 may be between 0.01 and 0.2 μm. In an embodiment, the area of the contact layer 18 is 1˜25% of the area of the mesa portion M, for example, 1˜20%, 1˜ 15%, or 1˜10%, and the area of the contact layer 18 is 1˜12% of the area of the semiconductor element 1, for example, 1˜10% or 1˜5%.

The current spreading layer 301 is formed on a portion of the contact layer 18 and is electrically connected to the second semiconductor layer 122. The current spreading layer 301 includes a metal material, such as chromium (Cr), titanium (Ti), tungsten (W), gold (Au), aluminum (Al), rhodium (Rh), indium (In), tin (Sn), nickel (Ni), platinum (Pt), silver (Ag), beryllium (Be), germanium (Ge), or a stack or an alloy of the aforementioned materials. For example, the current spreading layer 301 includes a metal stack consisted of an adhesive metal layer, a barrier metal layer, and a reflective metal layer. In an embodiment, the thickness of the current spreading layer 301 is between 0.3˜3 μm. In other embodiments (not shown), the semiconductor element 1 may not include the current spreading layer 301, the first opening 501 exposes the contact layer 18, and the first electrode layer 20A is filled into the first opening 501 to connect with the contact layer 18.

In another embodiment (not shown), the semiconductor element 1 further includes an another current spreading layer, which is disposed on the upper surface 121a of the first semiconductor layer 121 in the recessed portion R and is electrically connected to the first semiconductor layer 121. The insulating layer 50 includes a second opening 502 (described later) in the recessed portion R, which exposes the another current spreading layer on the upper surface 121a of the first semiconductor layer 121. The electrode layer (the second electrode layer 30A on the recessed portion R, to be described later) fills the second opening 502 and connects to the another current spreading layer on the upper surface 121a of the first semiconductor layer 121. The another current spreading layer electrically connected to the first semiconductor layer 121 and the current spreading layer 301 electrically connected to the second semiconductor layer 122 may include the same or different metal stack.

The thickness of the insulating layer 50 may range from 0.2 μm to 3 μm, and the insulating layer 50 covers the semiconductor stack 12, the contact layer 18, and the current spreading layer 301. The insulating layer 50 includes a first opening 501 on the mesa portion M to expose the current spreading layer 301, and a second opening 502 in the recessed portion R to expose the upper surface 121a of the first semiconductor layer 121. As shown in FIG. 1B, the first opening 501 and the second opening 502 each includes a sidewall, and an acute angle is formed between the sidewall and the XY plane. In an embodiment, the acute angle is between 20 degrees and 80 degrees, in another embodiment, the acute angle is between 30 degrees and 60 degrees. Base on the acute angle design, the first electrode layer 20A and the second electrode layer 30A respectively formed above the first opening 501 and the second opening 502 have better coverage on the first opening 501 and the second opening 502. In an embodiment, in order to reflect more light of a specific wavelength, the insulating layer 50 may also include a distributed Bragg reflector (DBR).

The insulating layer 50 includes the insulating materials, such as the organic or the inorganic insulating materials. The organic insulating material includes SU-8 photoresist, benzocyclobutene (BCB), perfluorocyclobutane (PFCB), epoxy, acrylic resin, cyclic olefin copolymer (COC), poly methyl methacrylate (PMMA), polyethylene terephthalate (PET), polycarbonate (PC), polyetherimide, or fluorocarbon polymer. The inorganic material includes silicone, glass, silicon oxide, silicon nitride, silicon oxynitride, niobium oxide, hafnium oxide, titanium oxide, magnesium fluoride, or aluminum oxide.

The insulating layer 50 may be a stack composed of multiple insulating layers or a single insulating layer. In an embodiment, the multiple insulating layers include different materials. In another embodiment, the insulating layer 50 includes a stack formed by alternately stacking one or more pairs of first sub-layer and second sub-layer (not shown) with different refractive indices. By selecting materials with different refractive indices and designed thicknesses, the insulating layer 50 can reflect the light within a specific wavelength range and/or incident angle range, thereby the insulating layer 50 is provided as a reflective structure. For example, the insulating layer 50 have a reflectivity of more than 60% for the main wavelength and/or peak wavelength of the light emitted from the semiconductor stack 12.

In other embodiments, the insulating layer 50 further includes layers other than the first sub-layer and the second sub-layer. For example, the insulating layer 50 includes a bottom layer (not shown) located between the first sub-layer, the second sub-layer and the semiconductor 12. That is, in the fabrication process, the bottom layer is first formed on the semiconductor stack 12, then the first and second sub-layers are formed on the bottom layer.

The bottom layer can serve to protect the semiconductor element or the semiconductor stack, such as blocking the external moisture from entering the semiconductor element. The bottom layer includes an insulating material, which may be the same as one of the first or second sub-layers, or different from both of the first sub-layer and the second sub-layer. The thickness of the bottom layer is greater than the thickness of each of the first sub-layer and the second sub-layer. In an embodiment, the formation method of the bottom layer may be different from that of the first sub-layer and the second sub-layer. For example, the bottom layer may be formed by chemical vapor deposition (CVD) preferably, plasma-enhanced chemical vapor deposition (PECVD). In another embodiment, the bottom layer may be formed by the same method as the first sub-layer and the second sub-layer, such as the bottom layer and the first and second sub-layers all are formed by chemical vapor deposition or physical vapor deposition methods, for example, evaporation, sputtering, or a combination thereof. Thus, the insulating layer 50 can be formed with a flat surface.

In another embodiment, the insulating layer 50 further includes an upper layer (not shown) located on the first sub-layer and the second sub-layer, and formed on the other side opposite to the second semiconductor layer 122. That is, in the manufacturing process, the first sub-layer and the second sub-layer are first formed on the semiconductor stack 12, and then the upper layer is formed. In an embodiment, the upper layer can increase the strength of the entirety of the insulating layer 50. For example, when the insulating layer 50 is subjected to an external force, the upper layer can prevent the insulating layer 50 from being cracked and damaged by the external force. The upper layer includes an insulating material, which can be the same as that of one of the first sub-layer and the second sub-layer, or different from that of both the first sub-layer and the second sub-layer. The thickness of the upper layer is greater than that of the first sub-layer and greater than that of the second sub-layer. Similar to the bottom layer described above, the formation method of the upper layer can be different from that of the first sub-layer and the second sub-layer, or the same as that of the first sub-layer and the second sub-layer. In another embodiment, the insulating layer 50 includes a stack composed of the first sub-layer and the second sub-layer, the bottom layer and/or the upper layer.

In another embodiment, the insulating layer 50 further includes a dense layer (not shown). The dense layer can be the lowermost layer or the uppermost layer of the insulating layer 50. The dense layer also can be formed between any two of the stack described above, the bottom layer, and the upper layer of the insulating layer 50. In an embodiment, the dense layer may be formed by atomic layer deposition (ALD) with a thickness of 50 Å to 2000 Å, preferably 100 Å to 1500 Å. The dense layer includes an insulating material, which may be the same as one of the first sub-layer and the second sub-layer or different from both of the first sub-layer and the second sub-layer. In an embodiment, the dense layer may conformally cover the structure below it, such as covering the semiconductor stack 12, and may protect the structure below it by virtue of its film quality characteristics with good step coverage, such as preventing moisture from entering the semiconductor stack 12. In another embodiment, the dense layer located on the top of the insulating layer 50 may increase the adhesion between the insulating layer 50 and the structure above it (e.g., an electrode layer, which will be described in detail later).

Optionally, in other embodiments (not shown), the insulating layer 50 also cover the sidewall S of the first semiconductor layer 121 and/or the bottom surface of the semiconductor stack 12.

The electrode layer is disposed on the insulating layer 50 and includes a metal material, such as chromium (Cr), titanium (Ti), tungsten (W), gold (Au), aluminum (Al), indium (In), tin (Sn), nickel (Ni), platinum (Pt), silver (Ag), or a stack or an alloy of the above materials. The electrode layer includes a first electrode layer 20A and a second electrode layer 30A. The first electrode layer 20A fills the first opening 501 and is electrically connected to the current spreading layer 301 and the contact layer 18. The second electrode layer 30A fills the second opening 502 and is electrically connected to the first semiconductor layer 121. Specifically, the first electrode layer 20A and the second electrode layer 30A serve as the current path for supplying power from an external source to the second semiconductor layer 122 and the first semiconductor layer 121, respectively. In an embodiment, as shown in FIGS. 1A and 2, the area of the second electrode layer 30A is greater than that of the first electrode layer 20A. The first electrode layer 20A and the second electrode layer 30A include a multilayer structure. For example, the metal structure of the first electrode layer 20A and the second electrode layer 30A connected to the external power source may be formed by alternately stacking gold (Au) layers and tin (Sn) layers, or alternately stacking tin (Sn) layers and silver (Ag) layers. Tin (Sn), gold (Au), or silver (Ag) may serve as the outermost metal layer of the first electrode layer 20A and the second electrode layer 30A. In an embodiment, the contact resistance between the second semiconductor layer 122 and the contact layer 18 is less than the contact resistance between the second semiconductor layer 122 and the second electrode layer 30A or the current spreading layer 301.

Referring to FIG. 2, the outer contour of the second semiconductor layer 122 of the semiconductor element 1 is substantially rectangular and includes two shorter sides E3 and E4, which are opposite to each other in the X direction. The length of the shorter side E3 or E4 corresponds to the width W of the second semiconductor layer 122. The outer contour of the second semiconductor layer 122 of the semiconductor element 1 further includes two longer sides E1 and E2, which are opposite to each other in the Y direction. The length of the longer side E1 or E2 corresponds to the length L of the second semiconductor layer 122. The contact layer 18 is substantially rectangular, and includes two shorter sides E7 and E8 opposite to each other in the X direction and two longer sides E5 and E6 opposite to each other in the Y direction. As shown in FIG. 2, in the X direction extending from the mesa portion M toward the recessed portion R, the shorter side E4 of the second semiconductor layer 122, the shorter side E8 of the contact layer 18, the shorter side E7 of the contact layer 18, and the shorter side E3 of the second semiconductor layer 122 are sequentially disposed. In the embodiment, a spacing is formed between the recessed portion R and the two shorter sides E3, E4, the two longer sides E1, E2 of the second semiconductor layer 122. Therefore, in the plan view of FIG. 2, the recessed portion R is surrounded by the second semiconductor layer 122. A spacing is formed between each side of the second semiconductor layer 122 and each side of the first semiconductor layer 121. That is, as shown in FIG. 1B, the upper surface 121a of the first semiconductor layer 121 includes a portion located on a periphery of the semiconductor stack 12, which surrounds the second semiconductor layer 122 and the active layer 123. The upper surface 121a of the first semiconductor layer 121 includes another portion, which forms the bottom surface of the recessed portion R. In another embodiment (not shown), the upper surface 121a of the first semiconductor layer 121 is not disposed on the periphery of the semiconductor stack 12, and the sidewall of the second semiconductor layer 122, the sidewall of the active layer 123, and the sidewall S of the first semiconductor layer 121 are directly connected to each other.

For the convenience of explanation, the distance between any two opposite sides is represented by “D_x1x2” in the figure, and x1 and x2 represent the numbers of the codes of the side mentioned above (for example, E1 to E8). For example, the distance between the shorter side E4 of the second semiconductor layer 122 and the shorter side E8 of the contact layer 18 is represented by D_48. The distance between the longer side E1 of the second semiconductor layer 122 and the longer side E5 of the contact layer 18 is represented by D_15, the distance between the shorter side E3 of the second semiconductor layer 122 and the shorter side E7 of the contact layer 18 is represented by D_37, and the distance between the recessed portion R and the short side E7 of the contact layer 18 is represented by D_R7. In an embodiment, the distance D_37 is greater than the distance D_R7, the distance D_15, the distance D_26, and the distance D_48, and the distance D_48 is less than or equal to the distance D_R7, the distance D_15, and the distance D_26. The distance D_15 is equal to, less than or larger than the distance D_26. In an embodiment, the distance D_48 can be between 0.5˜5 μm. In an embodiment, the distance D_48 is 2.5 to 15% of the length L of the second semiconductor layer 122, the distance D_R7 is 2.5 to 15% of the length L of the second semiconductor layer 122, the distance D_15 is 5 to 25% of the width W of the second semiconductor layer 122, and the distance D_26 is 5 to 25% of the width W of the second semiconductor layer 122. By providing a spacing between the edge of the contact layer 18 and the edge of the second semiconductor layer 122 and between the edge of the contact layer 18 and the edge of the recessed R, most of the current can be confined to the semiconductor stack 12 below the contact layer 18, that is, most of the carriers will combine in the active layer 123 below the contact layer 18, and the carriers in the semiconductor stack 12 are kept away from the sidewalls of the semiconductor stack 12 and the sidewalls of the recessed R, thereby reducing the non-radiative recombination effect occurring near the sidewalls of the semiconductor stack, so that the injected carriers combine in the effective light emitting area. When the semiconductor element 1 is operated at a specific current density, such as a current density of 0.1˜40 A/cm², a better photoelectric conversion efficiency can be obtained. The above-mentioned distance is not limited to the disclosure of this embodiment. Taking into account the size of the semiconductor element, the characteristics of the contact layer, such as the ability of lateral current conduction, the contact resistance of the interface between the contact layer and the semiconductor stack, and the operating current, the appropriate distance of the semiconductor element is obtained. According to the characteristics of different semiconductor stacks 12, such as the matching of the energy bands between the materials, the defect density, and the conductive characteristics of the electrode layers, the semiconductor stack 12 includes a higher external quantum efficiency (External Quantum Efficiency, EQE) within a specific current density range, and the area and position of the contact layer 18 can be designed according to this current density range and the operating current of the semiconductor element.

In a plan view (e.g., FIG. 2), the contact layer 18 covers the center area of the semiconductor stack 12, that is, the contact layer 18 is located on the main light emitting area of the semiconductor stack 12. In an embodiment, the area of the upper surface of the contact layer 18 is 20˜65% of the area of the upper surface of the second semiconductor layer 122, and the shortest distance between any side of the contact layer 18 and any side of the second semiconductor layer 122 is not less than 0.5% of the length of the shorter side (E3, E4) of the second semiconductor layer 122. The second electrode layer 30A covers part of the upper surface of the second semiconductor layer 122 and does not overlap with the contact layer 18, that is, the projection of the contact layer 18 on the semiconductor stack 12 and the projection of the second electrode layer 30A on the semiconductor stack 12 are not overlapped with each other. In an embodiment, the minimum distance between the contact layer 18 and the second electrode layer 30A is 0.3˜3 μm to avoid the short circuit and ensure the insulation therebetween.

As shown in FIG. 2, the contour of the upper surface of the second semiconductor layer 122 includes a first centroid C1, the contour of the upper surface of the contact layer 18 includes a second centroid C2, and the contour of the first opening 501 includes a third centroid C3. The third centroid C3 can be regarded as the center where the current is injected from the first electrode layer 20A into the active layer 123 or the semiconductor element 1, the first centroid C1 does not overlap with the second centroid C2, and the contact layer 18 covers the first centroid C1.

As shown in FIG. 2, the outer contour of the second semiconductor layer 122 is defined by two longer sides E1 and E2 and two shorter sides E3 and E4. The first centroid C1 can be regarded as the geometric center of the outer contour of the second semiconductor layer 122, which can be calculated by a standard geometric formula. The outer contour of the contact layer 18 is defined by two longer sides E5 and E6 and two shorter sides E7 and E8. The second centroid C2 can be regarded as the geometric center of the outer contour of the contact layer 18, which can be calculated by a standard geometric formula. In an embodiment, the contour of the first opening 501 includes a circle, an ellipse, a rectangle or other irregular shapes. If the contour of the first opening 501 is a symmetrical shape, it can be calculated by a standard geometric formula. If the outer contour of the second semiconductor layer 122, the outer contour of the contact layer 18 and the contour of the first opening 501 are asymmetrical or irregular shapes, the positions of the first centroid C1, the second centroid C2 and the third centroid C3 can be obtained from the area distribution integral calculation.

For the convenience of explanation, the distance between two centroids is represented by “dx1x2” in the drawings of the present application, and x1 and x2 represent the numbers of the codes of each centroid Cx. For example, the distance between the first centroid C1 and the second centroid C2 is d12, the distance between the first centroid C1 and the third centroid C3 is d13, and the distance between the second centroid C2 and the third centroid C3 is d23. In an embodiment, the distance d13 is greater than the distance d23, thereby the non-radiative recombination occurring on the sidewalls of the semiconductor stack is reduced, and the effective carrier recombination of the semiconductor element 1 is improved. The distance d23 can be greater than or equal to the distance d12, the distance between the third centroid C3 and the shorter side E4 of the second semiconductor layer 122 can be 2˜20% of the length L of the second semiconductor layer 122, the distance d12 between the first centroid C1 and the second centroid C2 can be 0.5˜49% of the length of the longer sides E1 or E2 of the second semiconductor layer 122 (i.e., the length L of the second semiconductor layer 122), and the distance d13 between the first centroid C1 and the third centroid C3 can be 15˜35% of the length L of the second semiconductor layer 122.

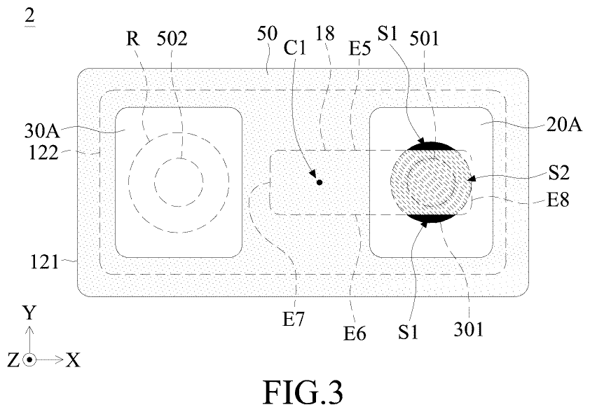

FIG. 3 illustrates a plan view of a semiconductor element 2 which is a variation example of the semiconductor element 1 of the first embodiment. The main difference between the embodiment (hereinafter referred to as the second embodiment) and the first embodiment is the width (the length in the Y direction) of the contact layer 18. In the second embodiment, the length of the contact layer 18 in the Y direction (equivalent to the length of the shorter side E7 or E8) is smaller than the length of the current spreading layer 301 in the Y direction. Accordingly, the current conducting layer 301 covers the top surface of the contact layer 18 and the sidewall of part of the contact layer 18 in the Y direction, and the current conducting layer 301 extends beyond the contact layer 18 to contact the second semiconductor layer 122 (a second portion). In other words, the current spreading layer 301 is located above the contact layer 18 and the second semiconductor layer 122, and the contact layer 18 is located above the second semiconductor layer 122. The current spreading layer 301 includes a first portion in contact with the contact layer 18 and the second portion in contact with the second semiconductor layer 122. The second portion of the current spreading layer 301 has a second contact surface S1 contacting the second semiconductor layer 122. The first portion of the current spreading layer 301 has a second contact surface S2 contacting the contact layer 18, wherein the area of the first contact surface S1 is smaller than the area of the second contact surface S2, and the contact resistance of the first contact surface S1 is greater than the contact resistance of the second contact surface S2. The second contact surface S2 is disposed between the two first contact surfaces S1. The contact layer 18 extends in the X direction to cover the first centroid C1, thereby spreading the current to the main effective light emitting area to improve the brightness of the semiconductor element 2.

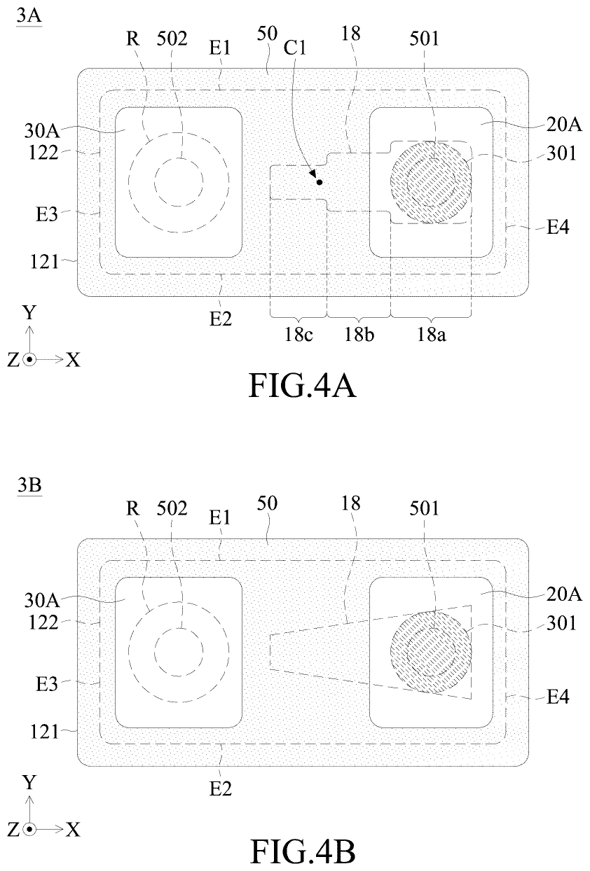

FIG. 4A illustrates a plan view of a semiconductor element 3A according to the third embodiment of the present application. FIG. 4B illustrates a schematic diagram of a variation example of the contact layer 18 of a semiconductor device 3B. The difference between the semiconductor element 3A, 3B and the semiconductor element 1 is that the width of the contact layer 18 of the semiconductor element 3A, 3B is not uniform in the X direction as shown in FIG. 4A and FIG. 4B. In the embodiment, in the X direction, the closer to the recessed portion R is, the smaller the width of the contact layer 18 of the semiconductor element 3A is. In other words, the portion of the contact layer 18 near the recessed portion R includes a width smaller than a width of the other portion of the contact layer 18 away from the recessed portion R. In an embodiment, the width of the contact layer 18 may be reduced in a stepwise (step-by step) manner (FIG. 4A) or in a continuous manner (FIG. 4B). Referring to FIG. 4A, the contact layer 18 includes a first portion 18a, a second portion 18b, and a third portion 18c sequentially connected to each other, wherein the third portion 18c is closer to the recessed portion R and the shorter side E3 of the second semiconductor layer 122. The portions each includes a width different from others. For example, the width of the third portion 18c is smaller than the width of the second portion 18b, and the width of the second portion 18b is smaller than the width of the first portion 18a. The overall shape of the contact layer 18 is reduced in a stepwise (step-by-step) manner. As shown in FIG. 4B, the width of the contact layer 18 of the semiconductor element 3B according to the present application is continuously reduced in the direction toward the recessed portion R, so that in the top view, the contact layer 18 has a shape formed in a trapezoid, a wedge or a triangle. The contact layer 18 includes a larger width on one side close to the shorter side E4 of the second semiconductor layer 122 and a smaller width on the other side close to the shorter side E3 of the second semiconductor layer 122. In an embodiment, the maximum width of the contact layer 18 is equivalent to the width of the first portion 18a in FIG. 4A, and is greater than or equal to the width of the current spreading layer 301. In some cases, for example, the semiconductor element is a light-emitting diode. When the current is conducted between the first electrode layer 20A and the second electrode layer 30A under the low current density (e.g., 0.1˜40 A/cm²), the current congestion is likely to occur near the sidewall of the recessed portion R, and therefore, the occurring opportunity of the non-radiative recombination of the carriers in this area increases. According to an embodiment of the present application, the above phenomenon is reduced by reducing the width of the contact layer 18 in the direction towards the recessed portion R, thereby the brightness of the semiconductor element 3A, 3B is improved. Although the second centroid C2, the third centroid C3, and the distance between the centroids are not indicated in FIG. 4A and FIG. 4B, according to the above embodiment, the distance d13 between the first centroid C1 and the third centroid C3 can be greater than the distance d23 between the second centroid C2 and the third centroid C3, and the distance d23 between the second centroid C2 and the third centroid C3 can be greater than or equal to the distance d12 between the first centroid C1 and the second centroid C2.

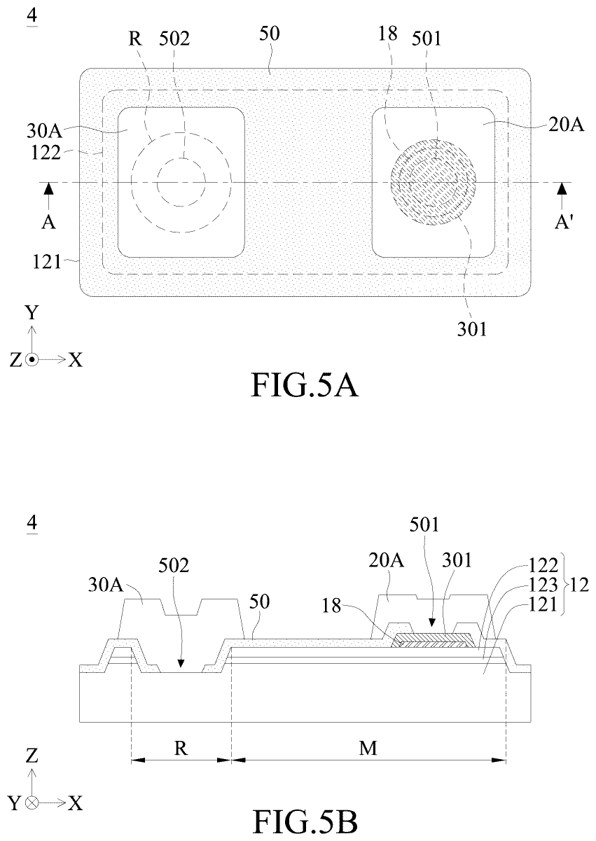

FIG. 5A illustrates a plan view of a semiconductor element 4 according to a fourth embodiment of the present application. FIG. 5B illustrates a cross-sectional view along line A-A′ in FIG. 5A. As shown in FIG. 5A, the difference between the semiconductor element 4 and the semiconductor element 1 is that the projection region of contact layer 18 on the second semiconductor layer 122 (i.e., on XY plane) does not exceed the projection region of the current spreading layer 301. In some embodiments, the contact layer 18 occupies 1˜25% of the area of second semiconductor layer 122 and 1˜12% of the area of the semiconductor element 4. In an embodiment, the current spreading layer 301 has a projection region which is smaller than that of the contact layer 18. In another embodiment, the current spreading layer 301 has a projection region which is larger than that of the contact layer 18, and the current spreading layer 301 covers the side surface of the contact layer 18 and contacts the second semiconductor layer 122. In detail, a first contact surface is formed between the current spreading layer 301 and the second semiconductor layer 122, a second contact surface is formed between the contact layer 18 and the second semiconductor layer 122, the area of the first contact surface is smaller than that of the second contact surface, and the contact resistance of the first contact surface is greater than the contact resistance of the second contact surface. In addition, the projected area of the contact layer 18 on the second semiconductor layer 122 is greater than or equal to the projected area of the first opening 501 on the second semiconductor layer 122. In another embodiment (not shown), the projected area of the contact layer 18 on the second semiconductor layer 122 may be smaller than the projected area of the first opening 501 on the second semiconductor layer 122. In an embodiment, the second electrode layer 30A and the second semiconductor layer 122 are overlapped with each other by an area which is less than 40% of an area of the second electrode layer 30A. By controlling the overlap ratio of the second electrode layer 30A and the second semiconductor layer 122, the parasitic capacitance formed in the region can be suppressed, and the capacitive coupling effect between the metal and the semiconductor can be reduced. In an embodiment, the insulating layer 50 located between the contact layer 18 and the first electrode layer 20A helps to reduce the parasitic capacitance therebetween. Specifically, the contact layer 18 and the insulating layer 50 are overlapped with each other by an area which is greater than 40% of an area of the contact layer 18.

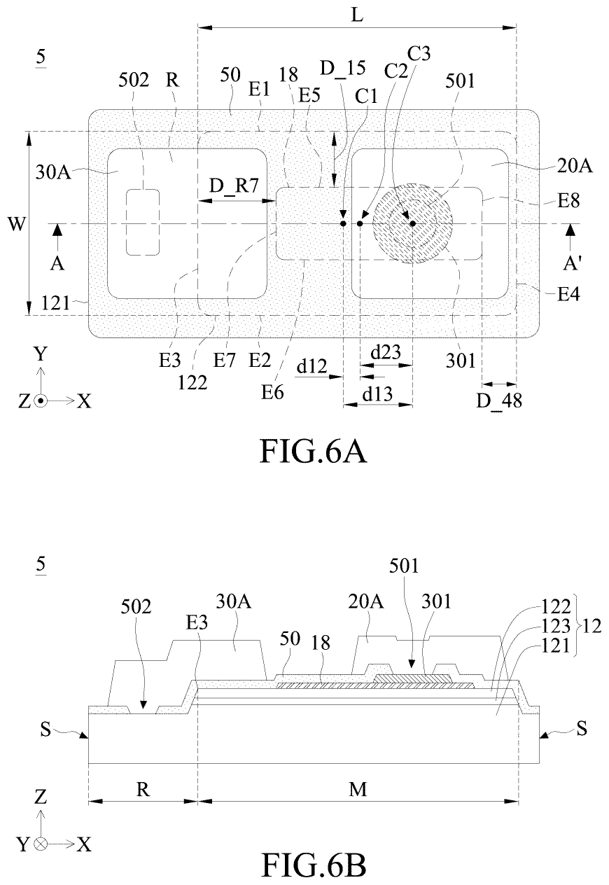

FIG. 6A illustrates a plan view of a semiconductor element 5 according to the fifth embodiment of the present application. FIG. 6B illustrates a cross-sectional view along the line A-A′ in FIG. 6A. The difference between the semiconductor element 5 and the semiconductor element 1 is that the recessed portion R of the semiconductor element 5 is located on one side of the semiconductor stack 12, one edge of the recessed portion R is the shorter side E3 of the second semiconductor layer 122, and the other edge of the recessed portion R is connected to the sidewall S of the first semiconductor layer 121. Referring to the plan view of FIG. 6A, the recessed portion R is adjacent to the shorter side E3 of the second semiconductor layer 122 and the sidewall S of the first semiconductor layer 121, and the recessed portion R is not completely surrounded by the second semiconductor layer 122. Similar to the semiconductor element 1, the first centroid C1 and the second centroid C2 of the semiconductor element 5 do not overlap, and the current spreading layer 301 covers the second centroid C2 of the upper surface contour of the contact layer 18. In an embodiment, the distance d13 between the first centroid C1 and the third centroid C3 is greater than the distance d23 between the second centroid C2 and the third centroid C3, and the distance d23 between the second centroid C2 and the third centroid C3 is greater than the distance d12 between the first centroid C1 and the second centroid C2. The second electrode layer 30A covers a portion of the upper surface of the second semiconductor layer 122 and does not overlap with the contact layer 18. In addition, the area of the upper surface of the contact layer 18 is 45˜90% of the area of the upper surface of the second semiconductor layer 122. In an embodiment, the distance D_48 between the shorter side E4 of the second semiconductor layer 122 and the shorter side E8 of the contact layer 18 and/or the distance D_15 between the longer side E1 of the second semiconductor layer 122 and the longer side E5 of the contact layer 18 is less than the distance D_R7 between the recessed portion R and the shorter side E7 of the contact layer 18. In an embodiment, the distance D_R7 between the recessed portion R and the short side E7 of the contact layer 18 is 2.5˜25% of the length L of the second semiconductor layer 122. The distance d13 between the first centroid C1 and the third centroid C3 is 15˜35% of the length L of the second semiconductor layer 122.

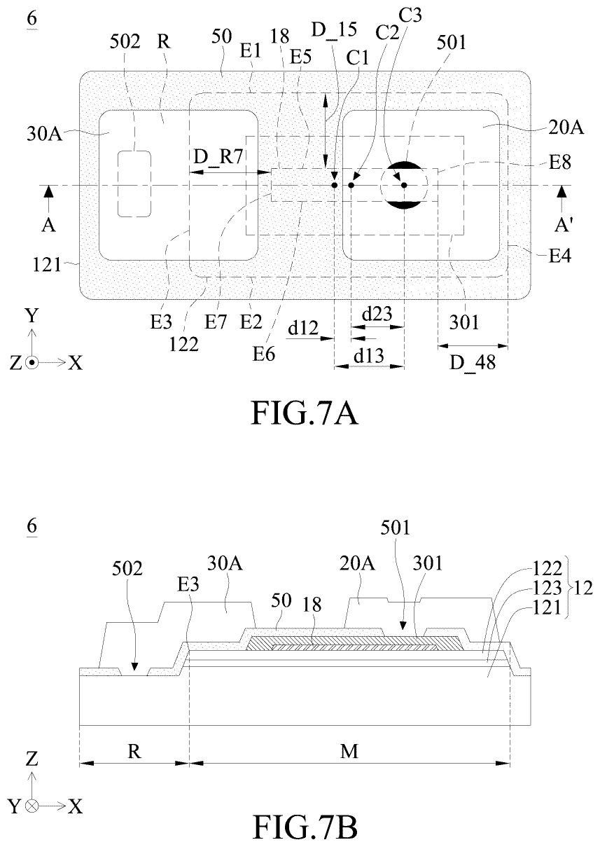

FIG. 7A illustrates a plan view of a semiconductor element 6 according to a sixth embodiment of the present application. FIG. 7B illustrates a cross-sectional view along line A-A′ in FIG. 7A. As shown in FIG. 7A, the difference between the semiconductor element 6 and the semiconductor element 5 is that the projection region of the contact layer 18 on the second semiconductor layer 122 (i.e., on the XY plane) does not exceed the projection region of the current spreading layer 301 on the second semiconductor layer 122. In an embodiment, the projection area of the current spreading layer 301 is larger than the projection area of the contact layer 18, and the current spreading layer 301 covers the side surface of the contact layer 18 and contacts the second semiconductor layer 122. In an embodiment, the area of the upper surface of the current spreading layer 301 is 45˜90% of the area of the upper surface of the second semiconductor layer 122. The current spreading layer 301 extends to cover the first centroid C1 of the upper surface of the second semiconductor layer 122 and cover the area between the first electrode layer 20A and the second electrode layer 30A. In an embodiment, when the material of the current spreading layer 301 includes a reflective metal, a larger light reflection area is provided to enhance the brightness of the semiconductor element 6. In an embodiment, the distance D_48 between the shorter side E4 of the second semiconductor layer 122 and the shorter side E8 of the contact layer 18 and/or the distance D_15 between the longer side E1 of the second semiconductor layer 122 and the longer side E5 of the contact layer 18 is smaller than the distance D_R7 between the recessed portion R and the shorter side E7 of the contact layer 18.

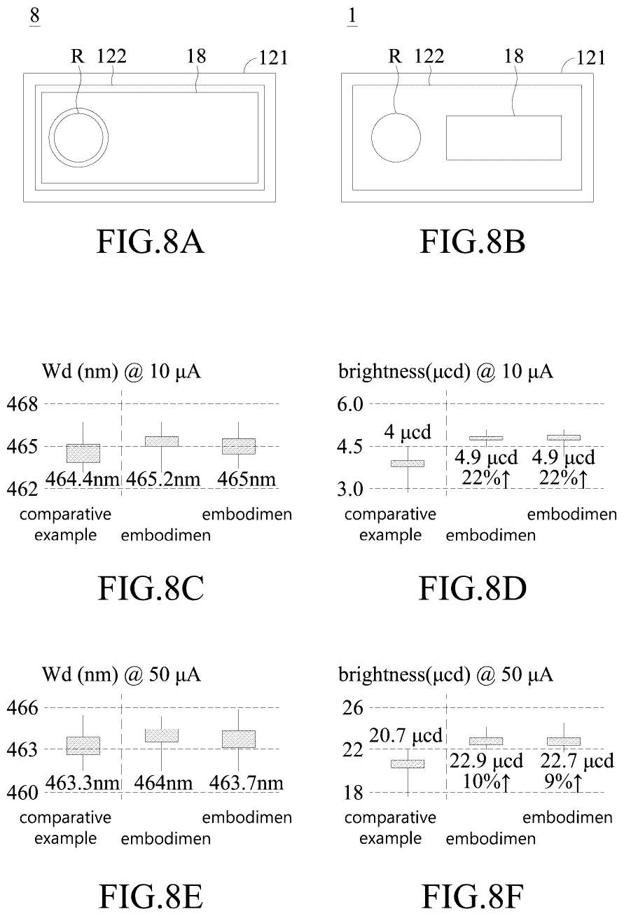

FIG. 8A illustrates a plan view of a semiconductor element 8 according to a comparative example. FIG. 8B illustrates a plan view of the semiconductor element 1 according to the first embodiment of the present application. FIGS. 8C to 8F illustrate the structure differences and the experimental comparisons between the semiconductor element 8 of the comparative example and the semiconductor element 1 of the first embodiment of the present application. FIGS. 8C to 8F illustrate two group experimental data of the semiconductor element 1. The semiconductor element 8 of the comparative example includes a structure similar to the semiconductor element 1 of the first embodiment, and both have a size of 20 μm×40 μm. The difference between the comparative example and the first embodiment is that, as shown in FIG. 8A (comparative example) and FIG. 8B (first embodiment), the contact layer 18 of the semiconductor element 8 of the comparative example is disposed inward a distance from the edge of the second semiconductor layer 122 and the recessed portion R, the contact layer 18 occupies 80% above of the projected area of the semiconductor element 8, while the contact layer 18 of the semiconductor element 1 occupies 1˜12% of the projected area of the semiconductor element 1. For illustration, FIG. 8A and FIG. 8B only illustrate the semiconductor stack, the recessed portion R and the contact layer 18, and the remaining structures can refer to FIG. 1A.

As shown in FIG. 8C and FIG. 8E, the range of the emission wavelength (Wd) distribution of the semiconductor element 1 of the first embodiment is smaller than that of the semiconductor element 8 of the comparative example operated under different currents (10 μA and 50 μA). The variation of the emission wavelength of the semiconductor element 8 of the comparative example is greater than that of the semiconductor element 1 of the first embodiment under the current of 10 μA (FIG. 8C) and the current of 50 μA (FIG. 8E). Compared with the semiconductor element 8, the semiconductor element 1 includes a smaller wavelength variation under different currents.

As shown in FIG. 8D and FIG. 8F, the brightness (μcd) of the semiconductor element 1 of the first embodiment is higher than the brightness of the semiconductor element 8 of the comparative example operated under different currents (10 μA and 50 μA). Compared with the semiconductor element 8 of the comparative example, the semiconductor element 1 of the first embodiment is 22% improved in brightness under a current of 10 μA (FIG. 8D), and is at least 9% improved in brightness under a current of 50 μA (FIG. 8F).

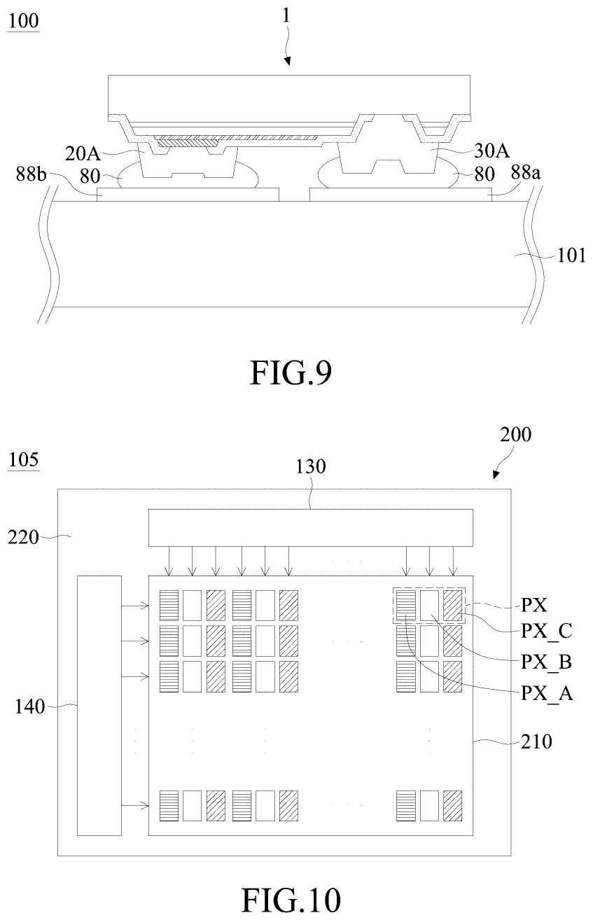

FIG. 9 illustrates a cross-sectional view of a light-emitting module 100 according to an embodiment of the present application. The light-emitting module 100 includes a circuit board 101, and the circuit board 101 includes a circuit (not shown) and the circuit bonding pads 88a and 88b. In FIG. 9, the semiconductor element 1 is illustrated as an example, but the first electrode layer 20 and the second electrode layer 30 of other semiconductor element according to the present application also can be flip-chipped bonded to the circuit bonding pads 88a and 88b via a conductive bonding layer 80. In an embodiment, the bonding method includes but is not limited to the eutectic bonding, the solder bonding, or the glue bonding, wherein the conductive bonding layer 80 includes an eutectic metal, a solder metal, or a conductive glue.

In different applications, the light-emitting module 100 can be provided as a display module or a lighting module. The light-emitting module 100 includes a plurality of semiconductor elements (not shown), and the plurality of semiconductor elements are arranged on the circuit board 101. The circuit provided on the circuit board 101 includes active electronic elements, such as transistors, and the circuit is electrically connected to the plurality of circuit bonding pads 88a and 88b to drive the plurality of semiconductor elements. In an embodiment, the light-emitting module 100 is provided as a display module, each semiconductor element can be a sub-pixel, and a wavelength conversion element is provided on each semiconductor element so that each sub-pixel emits different color light, and adjacent sub-pixels form a pixel unit. In detail, the wavelength conversion element includes the quantum dot, the phosphor, or the color filter. In another embodiment, each semiconductor element includes the semiconductor stack 12 of different materials so that each semiconductor element emits different color light.

FIG. 10 illustrates a schematic plan view of a display module 105 according to an embodiment of the present application. As shown in FIG. 10, the display module 105 includes a display substrate 200, and the display substrate 200 includes a display area 210 and a non-display area 220. A plurality of pixels PX are arranged in the display area 210 of the display substrate 200, and each pixel PX includes a first sub-pixel PX_A, a second sub-pixel PX_B, and a third sub-pixel PX_C. A data line driving circuit 130 and a scan line driving circuit 140 are provided in the non-display area 220. The data line driving circuit 130 connects a data line (not shown) of each pixel PX to transmit a data signal to each pixel PX. The scan line driving circuit 140 connects a scan line (not shown) of each pixel PX to transmit a scan signal to each pixel PX. The pixel PX includes a semiconductor element according to any of the above embodiments. Each sub-pixel emits light of a different color. In an embodiment, the first sub-pixel PX_A, the second sub-pixel PX_B, and the third sub-pixel PX_C can be a red sub-pixel, a green sub-pixel, and a blue sub-pixel, respectively. Alternatively, the semiconductor elements that emit light of different wavelengths can be used as sub-pixels to make each sub-pixel present a different color. Through the combination of red, green, and blue light emitted from each sub-pixel, the display module 105 can emit a full-color image.

According to an embodiment of the present application, a light-emitting apparatus (not shown) applicable to the optical communication is provided in the high-speed optical signal transmission and the data communication, which can be powered by the direct current or the alternating current and the modulation. The light-emitting apparatus includes the semiconductor element according to the above embodiments. Specifically, the light emitted by the semiconductor element can be modulated to carry the data signals, and is suitable for the visible light communications (VLC) or the short distance optical communications less than 100 meters, such as 1 to 100 mm.

The requirements of the transmission bandwidth have been increased in the optical communication applications. The traditional light-emitting elements are limited by the load capacitance and the driving performance, thus the modulation bandwidth is difficult to meet the needs from the high-frequency operation. In contrast, according to an embodiment of the present application, by reducing the area of the contact layer 18, reducing the overlapping area of the contact layer 18 and the current spreading layer 301, and/or increasing the overlapping area of the contact layer 18 and the insulating layer 50 to reduce the equivalent parasitic capacitance value, the transmission path of the carrier is limited, and the current modulation response is greatly increased. According to the measurement results, the semiconductor element 1, 2, 3A, 3B, 4, 5 or 6 of the embodiment can achieve a modulation bandwidth higher than 1 GHZ (at the −3 dB point corresponding frequency) under a driving current greater than 1 mA or a current density of 1000 amperes/square centimeter (A/cm²). The semiconductor element 1, 2, 3A, 3B, 4, 5 or 6 of the embodiment includes the excellent high-speed modulation capability and is suitable to be a data transmitter in the optical communication.

The elements of some of the above embodiments are described so that those with ordinary knowledge in the technical field to which this disclosure belongs can better understand the viewpoints of the embodiments of the disclosure. Those with ordinary skill in the art to which this disclosure belongs should understand that they can design or modify other processes and structures based on the embodiments of the disclosure to achieve the same purposes and/or advantages as the embodiments introduced here. Those with ordinary knowledge in the technical field to which this disclosure belongs should also understand that such equivalent structures do not deviate from the spirit and scope of the disclosure, and they can do various things without departing from the spirit and scope of this disclosure. Various changes, substitutions and replacements. Therefore, the protection scope of the present disclosure shall be subject to the scope of the appended patent application. In addition, although the disclosure has been disclosed with several preferred embodiments as above, this is not intended to limit the disclosure.

Reference throughout the specification to features, advantages, or similar language does not imply that all features and advantages that can be realized with the present disclosure should or can be realized in any single embodiment of the present disclosure. In contrast, language referring to features and advantages is to be understood to mean that a particular feature, advantage, or characteristic described in connection with the embodiment is of at least an embodiment of the present disclosure. Thus, discussions of features and advantages, and similar language, throughout the specification may, but are not necessarily, representative of the same embodiments.

Furthermore, the described features, advantages, and characteristics of the present disclosure may be combined in any suitable manner in one or more embodiments. From the description herein, those skilled in the relevant art will appreciate that the present disclosure may be practiced without one or more of the specific features or advantages of a particular embodiment. In other instances, additional features and advantages may be identified in certain embodiments that may not be present in all embodiments of the present disclosure.

What is claimed is:

1. A semiconductor element, including:
a semiconductor stack including a mesa portion and a recessed portion;
a contact layer formed on the mesa portion;
an insulating layer formed on the semiconductor stack and the contact layer, wherein the insulating layer includes a first opening formed on the mesa portion; and
an electrode layer formed on the insulating layer, and the electrode layer is electrically connected to the contact layer,
wherein in a plan view, the mesa portion includes a first centroid, the contact layer includes a second centroid, and the first opening includes a third centroid, and a distance between the first centroid and the third centroid is greater than a distance between the second centroid and the third centroid.

2. The semiconductor element according to claim 1, wherein in the plan view, the contact layer includes a dimension decreased in a direction toward the recessed portion.

3. The semiconductor element according to claim 1, wherein the contact layer includes multiple portions with different widths.

4. The semiconductor element according to claim 1, wherein, in a top view, the contact layer has a shape formed in a trapezoid, a wedge or a triangle.

5. The semiconductor element according to claim 1, wherein the insulating layer further includes a second opening located in the recessed portion, the electrode layer includes a first electrode layer and a second electrode layer, the first electrode layer is formed on the mesa portion and is electrically connected to the contact layer, and the second electrode layer is formed in the recessed portion and is electrically connected to the semiconductor stack.

6. The semiconductor element according to claim 5, wherein a projection of the contact layer on the semiconductor stack and a projection of the second electrode layer on the semiconductor stack are not overlapped with each other.

7. The semiconductor element according to claim 5, wherein the second electrode layer and the second semiconductor layer are overlapped with each other by an area which is less than 40% of an area of the second electrode layer.

8. The semiconductor element according to claim 5, further including a current spreading layer formed on the contact layer, wherein the current spreading layer includes a first portion having a first contact surface and contacting the contact layer, and a second portion having a second contact surface and contacting the second semiconductor layer, the first contact surface is smaller than the second contact surface.

9. The semiconductor element according to claim 8, wherein the first electrode layer is electrically connected to the current spreading layer.

10. The semiconductor element according to claim 8, wherein the current spreading layer has a projection region which is smaller than that of the contact layer on the second semiconductor layer.

11. The semiconductor element according to claim 8, wherein the current spreading layer has a projection region which is larger than that of the contact layer on the second semiconductor layer.

12. The semiconductor element according to claim 1, wherein the semiconductor stack sequentially includes a first semiconductor layer, an active layer, and a second semiconductor layer, and the contact layer is directly formed on the second semiconductor layer.

13. The semiconductor element according to claim 12, wherein the second semiconductor layer is substantially rectangular, and includes two opposite shorter sides and two opposite longer sides, and a distance between any side of the contact layer and any side of the second semiconductor layer is not less than 0.5% of a length of the shorter side of the second semiconductor layer.

14. The semiconductor element according to claim 13, wherein a distance between the first centroid and the second centroid is 0.5%˜49% of a length of one of the two opposite longer sides.

15. The semiconductor element according to claim 1, wherein a shortest distance between an edge of the contact layer and an edge of the second semiconductor layer is shorter than a shortest distance between an edge of the contact layer and an edge of the recessed portion.

16. The semiconductor element according to claim 1, wherein, in a plan view, the contact layer occupies 1% to 25% of an area of the mesa portion.

17. The semiconductor element according to claim 1, wherein the shortest side of the semiconductor element has a length of 2 to 20 μm.

18. The semiconductor element according to claim 1, wherein, in a plan view, the contact layer occupies 1˜12% of an area of the semiconductor element.

19. An optical communication device, comprising the semiconductor element according to claim 1.

20. A method for using an optical communication device according to claim 19, comprising the steps of: operating the optical communication device at a current greater than 1 mA, wherein the optical communication device includes a bandwidth greater than 1 GHz at-3 dB.
